(19) United States
(12) Patent Application Publication
(10) Pub. No.: US 2024/0215317 A1
(43) Pub. Date: Jun. 27, 2024

(54) DISPLAY DEVICE, DISPLAY PANEL AND METHOD FOR MANUFACTURING THE DISPLAY PANEL

(71) Applicants: BOE TECHNOLOGY GROUP CO., LTD., Beijing (CN); YUNNAN INVENSIGHT OPTOELECTRONICS TECHNOLOGY CO., LTD., Yunnan (CN)

(72) Inventors: Shengji YANG, Beijing (CN); Xue DONG, Beijing (CN); Hui WANG, Beijing (CN); Xiaochuan CHEN, Beijing (CN); Pengcheng LU, Beijing (CN); Kuanta HUANG, Beijing (CN); Dacheng ZHANG, Beijing (CN)

(21) Appl. No.: 17/915,525

(22) PCT Filed: Aug. 19, 2021
(86) PCT No.: PCT/CN2021/113638

§ 371 Date: Feb. 23, 2023

(51) Int. Cl. H10K 59/122; H10K 59/12

(52) U.S. Cl. CPC H10K 59/122; H10K 59/1201

(57) ABSTRACT

A display device, a display panel and a method for manufacturing the display panel are provided. The display panel includes: a driving backplane including a substrate, at least one wiring layer and a planarization layer; a first electrode layer including first electrodes spaced apart from each other; a pixel definition layer exposing each of the first electrodes, the pixel definition layer being provided with at least one separation protrusion which protrudes along a direction away from the substrate, and an orthographic projection of the separation protrusion on the planarization layer being located outside the first electrodes; a conductive shielding layer insulated from the first electrodes; a light emitting layer covering the pixel definition layer and the first electrodes, the light emitting layer protruding at the at least one separation protrusion, and the light emitting layer being electrically connected to the conductive shielding layer; and a second electrode.

### RELATED APPLICATIONS

The present application is the national stage entry of PCT/CN2021/113638, filed on Aug. 19, 2021, the entire disclosure of which is incorporated herein by reference.

### TECHNICAL FIELD

The present disclosure relates to the display technical field, and in particular, to a display device, a display panel and a method for manufacturing the display panel.

### BACKGROUND

With the development of display technologies, display panels have been widely used in various electronic devices such as mobile phones to realize image display and touch operations. The Organic Light Emitting Diode (OLED) display panel is a relatively common one. However, the color gamut of existing display panels still needs to be improved.

It should be noted that the information disclosed in the background section above is only used to enhance the understanding of the background of the present disclosure, and therefore may include information that does not constitute the prior art known to those skilled in the art.

### SUMMARY

An objective of the present disclosure is to provide a display device, a display panel and a method for manufacturing the display panel.

According to an aspect of the present disclosure, there is provided a display panel, including:
a driving backplane including a substrate, at least one wiring layer and a planarization layer, wherein the at least one wiring layer is arranged on a side of the substrate, and the planarization layer covers the at least one wiring layer;
a first electrode layer arranged on a surface of the planarization layer away from the substrate, and including a plurality of first electrodes spaced apart from each other;
a pixel definition layer arranged on the surface of the planarization layer away from the substrate and exposing each of the plurality of first electrodes, wherein the pixel definition layer is provided with at least one separation protrusion which protrudes along a direction away from the substrate, and an orthographic projection of the at least one separation protrusion on the planarization layer is located outside the first electrodes;
a conductive shielding layer arranged on a side of the planarization layer away from the substrate and insulated from the first electrodes, wherein an orthographic projection of the conductive shielding layer on the planarization layer is located outside the first electrodes;
a light emitting layer covering the pixel definition layer and the first electrodes, wherein the light emitting layer protrudes at the at least one separation protrusion, and the light emitting layer is electrically connected to the conductive shielding layer; and a second electrode covering the light emitting layer.

In an example embodiment of the present disclosure, the conductive shielding layer covers at least a partial region of the at least one separation protrusion, and the light emitting layer covers the conductive shielding layer and is in direct contact with the conductive shielding layer.

In an example embodiment of the present disclosure, the conductive shielding layer is connected to the second electrode.

In an example embodiment of the present disclosure, the at least one separation protrusion includes at least one annular separation ring, and one of the at least one separation ring surrounds outside of one of the first electrodes;
the conductive shielding layer includes at least one shielding ring, and at least partial region of one of the at least one protrusion is provided with one of the at least one shielding ring; and
any one of the at least one separation ring and a shielding ring which covers the one of the at least one separation ring surrounds a same one of the first electrodes.

In an example embodiment of the present disclosure, the number of the at least one separation ring is the same as the number of the first electrodes, and each of the first electrodes is surrounded by one of the at least one separation ring, and at least partial region of each of the at least one separation ring is covered by one of the at least one shielding ring.

In an example embodiment of the present disclosure, the at least one separation ring is connected to form an integral structure, and the at least one shielding ring is connected to form an integral structure.

In an example embodiment of the present disclosure, the at least one shielding ring is connected to the second electrode.

In an example embodiment of the present disclosure, at least a part of the at least one shielding ring is connected to the second electrode through at least one first via hole penetrating the light emitting layer, and an orthographic projection of the at least one first via hole on the planarization layer is located between two adjacent ones of the plurality of first electrodes.

In an example embodiment of the present disclosure, the driving backplane includes a pixel region and a peripheral region located outside the pixel region;
an orthographic projection of each of the plurality of first electrodes on the driving backplane is located in the pixel region;
an orthographic projection of an edge of the second electrode on the driving backplane is located in the peripheral region;
the conductive shielding layer further includes at least one connection body connected to the at least one shielding ring, and an orthographic projection of each of the at least one connection body on the driving backplane extends from the pixel region to the peripheral region; and
the second electrode is connected to the at least one shielding ring through the at least one connection body.

In an example embodiment of the present disclosure, at least one of the wiring layer includes a connection portion connected to the second electrode, and the at least one shielding ring is connected to the connection portion through a second via hole penetrating the planarization layer.

In an example embodiment of the present disclosure, the conductive shielding layer is arranged on the surface of the planarization layer away from the substrate, and is spaced apart from the first electrodes.

In an example embodiment of the present disclosure, the conductive shielding layer includes a first conductive layer, a second conductive layer and a third conductive layer which are sequentially stacked in a direction away from the substrate.

In an example embodiment of the present disclosure, materials of the first conductive layer and the third conductive layer are both metal titanium, and a material of the second conductive layer is metal aluminum.

In an example embodiment of the present disclosure, the pixel definition layer has at least one extension portion, each of the at least one the extension portion is arranged on a surface of a corresponding one of the first electrodes away from the substrate, and has an opening exposing the corresponding one of the first electrodes;
wherein a surface of each of the at least one separation protrusion away from the driving backplane is located on a side of the at least one extension portion away from the driving backplane.

In an example embodiment of the present disclosure, the pixel definition layer has a groove between one of the at least one separation protrusion and an adjacent extension portion.

In an example embodiment of the present disclosure, the light emitting layer includes multiple light emitting sub-layers connected in series, and at least one of the multiple light emitting sub-layers is connected in series with an adjacent one of the light emitting sub-layers through a charge generation layer.

In an example embodiment of the present disclosure, the conductive shielding layer covers a partial region of a surface of each of the at least one the separation protrusion away from the substrate;
the second electrode protrudes in a region corresponding to the at least one separation protrusion to form a first protruding region; and
a region of the first protruding region corresponding to the conductive shielding layer protrudes in a direction away from the conductive shielding layer to form a second protruding region.

According to an aspect of the present disclosure, there is provided a method for manufacturing a display panel, including:
forming a driving backplane, wherein the driving backplane includes a substrate, at least one wiring layer and a planarization layer, the at least one wiring layer is arranged on a side of the substrate, and the planarization layer covers the at least one wiring layer;
forming a first electrode layer on a surface of the planarization layer away from the substrate, wherein the first electrode layer includes a plurality of first electrodes spaced apart from each other;
forming a pixel definition layer on the surface of the planarization layer away from the substrate, wherein the pixel definition layer exposes each of the plurality of first electrodes, the pixel definition layer is provided with at least one separation protrusion which protrudes along a direction away from the substrate, and an orthographic projection of the at least one separation protrusion on the planarization layer is located outside the first electrodes;
forming a conductive shielding layer covering at least a partial region of the at least one separation protrusion;
forming a light emitting layer covering the pixel definition layer, the plurality of first electrodes and the conductive shielding layer, wherein the light emitting layer protrudes at the at least one separation protrusion, and the light emitting layer is in direct contact with the conductive shielding layer; and
forming a second electrode covering the light emitting layer.

According to an aspect of the present disclosure, there is provided a method for manufacturing a display panel, including:
forming a driving backplane, wherein the driving backplane includes a substrate, at least one wiring layer and a planarization layer, the at least one wiring layer is arranged on a side of the substrate, and the planarization layer covers the at least one wiring layer;
forming a first electrode layer on a surface of the planarization layer away from the substrate, wherein the first electrode layer includes a plurality of first electrodes spaced apart from each other;
forming a conductive shielding layer on the surface of the planarization layer away from the substrate, wherein the conductive shielding layer is spaced apart from the first electrodes;
forming a pixel definition layer on the surface of the planarization layer away from the substrate, wherein the pixel definition layer exposes each of the plurality of first electrodes, the pixel definition layer is provided with at least one separation protrusion which protrudes along a direction away from the substrate, and an orthographic projection of the at least one separation protrusion on the planarization layer is located outside the first electrodes;
forming a light emitting layer covering the pixel definition layer and the plurality of first electrodes, wherein the light emitting layer protrudes at the at least one separation protrusion, and the light emitting layer is electrically connected with the conductive shielding layer; and
forming a second electrode covering the light emitting layer.

According to an aspect of the present disclosure, there is provided display device, including the display panel according to any one of the above embodiments.

It is to be understood that the foregoing general description and the following detailed description are exemplary and explanatory only, and are not restrictive of the present disclosure.

### BRIEF DESCRIPTION OF THE DRAWINGS

The accompanying drawing, which are incorporated herein and form a part of the specification, illustrate the embodiments of the present disclosure and, together with the description, further serve to explain the principles of the embodiments of the present disclosure. Obviously, the drawings in the following description are only some embodiments of the present disclosure. For those of ordinary skill in the art, other drawings can be obtained based on these drawings without creative work.

FIG. 1 is a circuit schematic diagram showing electric leakage of light emitting units in the related art.

FIG. 2 is a schematic structural diagram showing the electric leakage of the light emitting units in the related art.

FIG. 3 is a spectrogram of a light emitting unit in the related art.

FIG. 4 is a schematic diagram of a display panel according to an embodiment of the present disclosure.

FIG. 5 is a top view of a driving backplane in the display panel according to an embodiment of the present disclosure.

FIG. 6 is a top view of a pixel definition layer and a conductive shielding layer in the display panel according to an embodiment of the present disclosure.

FIG. 7 is a schematic diagram of a display panel according to an embodiment of the present disclosure.

FIG. 8 is a schematic diagram of a display panel according to an embodiment of the present disclosure.

FIG. 9 is a schematic diagram of a display panel according to an embodiment of the present disclosure.

FIG. 10 is a schematic diagram of a light emitting layer in the display panel according to an embodiment of the present disclosure.

FIG. 11 is a schematic circuit diagram showing preventing of electric leakage of the display panel of the present disclosure.

FIG. 12 is a spectrogram of a display panel according to an embodiment of the present disclosure.

FIG. 13 is a voltage-brightness schematic diagram of a display panel according to an embodiment of the present disclosure.

FIG. 14 is a schematic diagram of a voltage-chromaticity coordinate of a red sub-pixel in a display panel according to an embodiment of the present disclosure.

FIG. 15 is a schematic diagram of a voltage-chromaticity coordinate of a blue sub-pixel in a display panel according to an embodiment of the present disclosure.

FIG. 16 is a schematic diagram of a voltage-chromaticity coordinate of a green sub-pixel in a display panel according to an embodiment of the present disclosure.

FIG. 17 to FIG. 20 are schematic structural diagrams in some steps of a method for manufacturing a display panel according to an embodiment of the present disclosure.

FIG. 21 and FIG. 22 are schematic flowcharts of methods for manufacturing a display panel according to embodiments of the present disclosure.

### LISTING OF REFERENCE NUMBERS

1: driving backplane; 110: pixel region; 120: peripheral region; 101: substrate; 1011: well region; 1012: doped region; 102: gate; 103: wiring layer; 1031: first wiring layer; 1031S: source; 1031D: drain; 1032: second wiring layer; 1032a: connection portion; 104: planarization layer;
2: first electrode layer; 21: first electrode; 201: first layer; 202: second layer; 203: third layer; 204: fourth layer;
3: pixel definition layer; 31: opening; 32: separation protrusion; 321: separation ring; 33: extension portion; 34: groove;
4: conductive shielding layer; 401: first conductive layer; 402: second conductive layer; 403: third conductive layer; 41: shielding ring; 42: connection body;
5: light emitting layer; 51: light emitting sub-layer; 52: charge generation layer; 001: light emitting unit;
6: second electrode; 61: first protruding region; 62: second protruding region;
7: color filter layer; 71: light filtering portion; 72: light shielding portion;
8: first encapsulation layer; 81: first encapsulation sub-layer; 82: second encapsulation sub-layer; 83: third encapsulation sub-layer;
9: second encapsulation layer;
10: transparent cover;
11: light extraction layer;
H1: first via hole; H2: second via hole; H3: third via hole.

### DETAILED DESCRIPTION

Example embodiments will now be described more fully with reference to the accompanying drawings. However, the example embodiments can be implemented in various forms and should not be construed as being limited to the examples set forth herein; rather, providing these embodiments makes the present disclosure more comprehensive and complete, and conveys the concepts of the example embodiments comprehensively to those skilled in the art. The same reference numbers in the drawings denote the same or similar structures, and thus their detailed descriptions will be omitted. Furthermore, the drawings are merely schematic illustrations of the present disclosure and are not necessarily drawn to scale.

The terms “a”, “an”, “the”, “said” and “at least one” are used to indicate the presence of one or more elements/components/etc; the terms “include/comprise” and “have” are open terms and are meant to be inclusive, and mean that additional elements/components/etc may be present in addition to the listed elements/components/etc; the terms “first”, “second” and “third” etc and only used as markers, and do not constitute a limit on the number of associated objects.

In the related art, a Micro Organic Light Emitting Diode (Micro OLED) is a display panel developed in recent years, and the Micro OLED light emitting devices contained therein usually have a size of less than 100 μm. OLED on silicon display panel is a more common one. The OLED on silicon can not only realize active addressing of pixels, but also realize the preparation of CMOS circuits including pixel circuits, timing control (TCON) circuits, overcurrent protection (OCP) circuits on a silicon substrate by semiconductor manufacturing processes, which is conducive to reducing the size of the system and achieving light weight.

Taking the OLED on silicon display panel as an example, it may include a driving backplane and a light emitting layer. A light emitting functional layer is arranged on a side of the driving backplane, and includes a plurality of light emitting devices. A light emitting unit may include one or more serially connected OLED light emitting devices. Each light emitting device includes a first electrode (anode), a light emitting layer and a second electrode (cathode) stacked in sequence in a direction away from the driving backplane. By applying electrical signals to the first electrode and the second electrode, the light emitting layer can be driven to emit light. The specific light emitting principles of the OLED light emitting device are not described in detail here.

In addition, the light emitting layers of the light emitting devices may be formed by direct vapor deposition using a fine mask (FMM). The light emitting layers of the light emitting devices are spaced apart, emit light independently, and realize color display. However, it is difficult to achieve high PPI (pixel density) due to the limitations of the fine mask manufacturing processes. Therefore, color display may also be achieved by combining monochromatic light or white light with a color filter. That is, the light emitting devices share a same continuous light emitting layer, the light emitting layer may emit white light or other monochromatic light, and the color filter layer has a plurality of light filtering regions corresponding to the multiple light emitting units one to one. One light filtering region and a corresponding light emitting unit may form a sub-pixel. A plurality of sub-pixels form a pixel. The color of the light that can pass through different light filtering regions may be different, and thus the light emitting colors of different sub-pixels are different. A same pixel includes multiple sub-pixels with different colors. For example, a pixel may include three sub-pixels with light emitting colors of red (R), green (G), and blue (B). Accordingly, color display can be realized by a plurality of pixels.

However, if the light emitting layer is a continuous whole-layer structure, electric leakage is likely to occur between a light emitting unit and surrounding light emitting units, resulting in cross-color. The reasons for the cross-color will be analyzed below with reference to drawings.

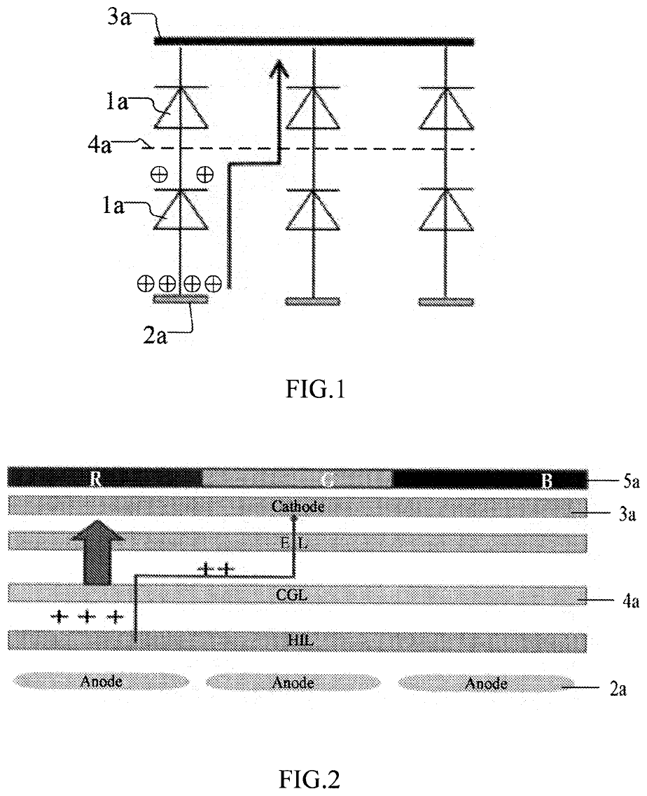

As shown in FIG. 1, each light emitting unit may include two light emitting devices connected in series. The two light emitting devices share a first electrode 2a and a second electrode 3a. There are two light emitting sub-layers 1a between the first electrode 2a and the second electrode 3a. The two light emitting sub-layers 1a are connected in series through a charge generation layer 4a to form a light emitting layer. As can be seen from FIG. 1 and FIG. 2, positive charges (holes) are transferred between two adjacent light emitting units through the charge generation layer 4a, while as can be seen from FIG. 2, when the light emitting unit corresponding to the red light filtering region R in the color filter layer 5a emits light, the light emitting unit corresponding to the green light filtering region G in the color filter layer 5a also emits light due to the influence of the electric leakage, resulting in a decrease in the luminous purity of a single pixel and a decrease in the color gamut of the entire display panel.

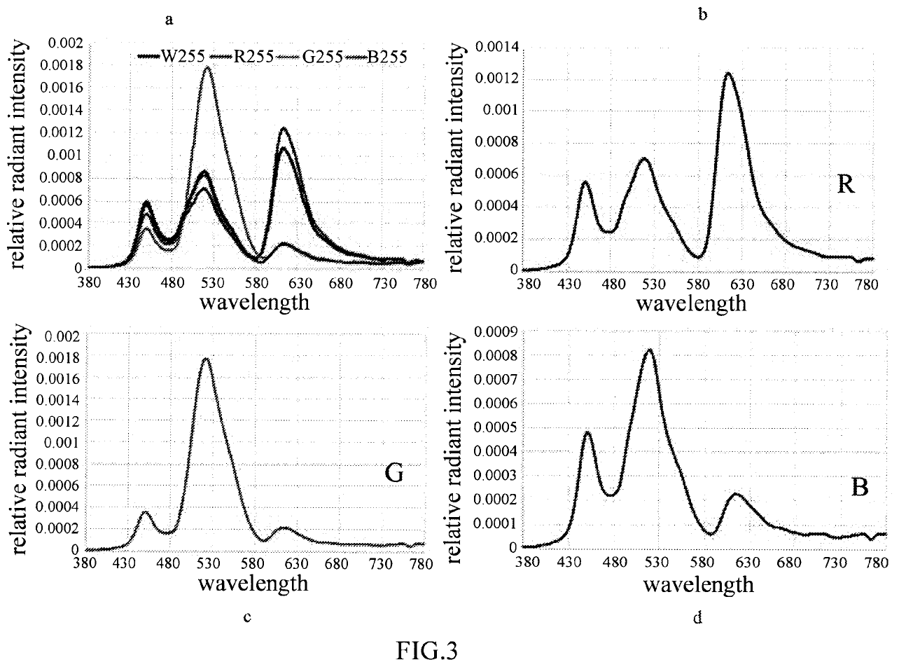

FIG. 3 shows a spectrogram when three sub-pixels (i.e., the red (R), green (G), and blue (B) sub-pixels) are turned on at the same time (shown in a in FIG. 3) and a spectrogram when three sub-pixels (i.e., the red (R), green (G), and blue (B) sub-pixels) are turned on separately (shown in b to c in FIG. 3). According to the wavelength, it can be seen that when the three sub-pixels are turned on separately, light of different colors escapes from adjacent sub-pixels. For example, as shown in a in FIG. 3, when the R sub-pixel emits red light, there are peaks at the wavelengths corresponding to blue and green light, which are generated by blue and green light. This results in a reduction in the color gamut of the entire display panel. According to calculations, the color gamut index (NTSC) of the display panel is only 30%.

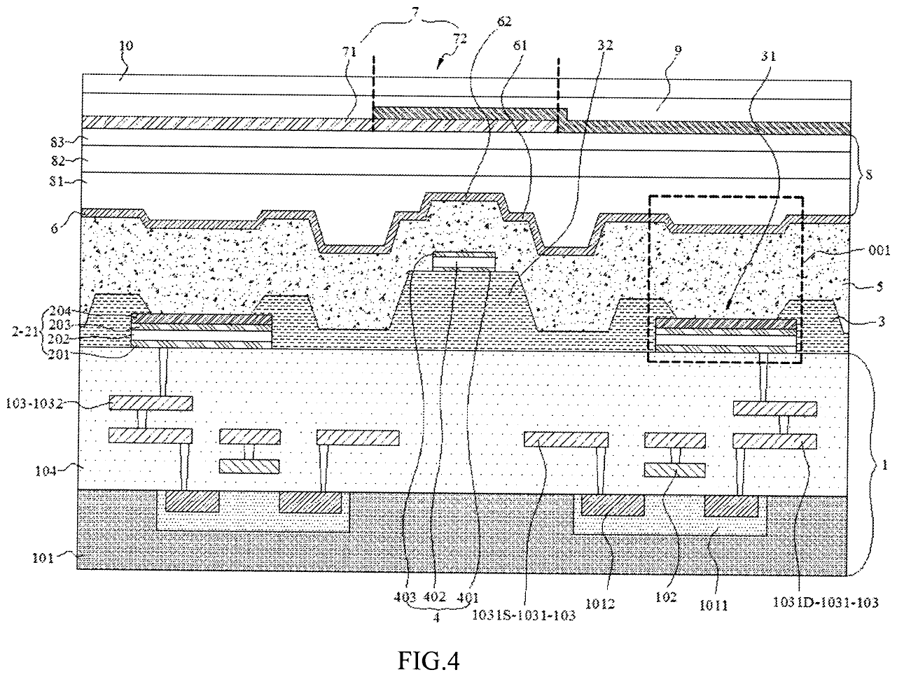

An embodiment of the present disclosure provides a display panel. As shown in FIG. 4 to FIG. 6, the display panel may include a driving backplane 1, a first electrode layer 2, a pixel definition layer 3, a conductive shielding layer 4, a light emitting layer 5, a second electrode 6 and a color filter layer 7.

The driving backplane 1 includes a substrate 101, at least one wiring layer 103 and a planarization layer 104. The at least one wiring layer 103 is arranged on a side of the substrate 101. The planarization layer 104 covers the at least one wiring layer 103.

The first electrode layer 2 is arranged on a surface of the planarization layer 104 away from the substrate 101, and includes a plurality of first electrodes 21 spaced apart from each other.

The pixel definition layer 3 is arranged on the surface of the planarization layer 104 away from the substrate 101 and exposes each of the plurality of first electrodes 21. The pixel definition layer 3 is provided with at least one separation protrusion 32 which is raised along a direction away from the substrate 101, and an orthographic projection of the at least one separation protrusion 32 on the planarization layer 104 is located outside the first electrodes 21.

The conductive shielding layer 4 is arranged on a side of the planarization layer 104 away from the substrate 101 and is insulated from the first electrode layer 2.

The light emitting layer 5 covers the pixel definition layer 3 and the first electrodes 21, and the light emitting layer 5 protrudes at the at least one separation protrusion 32. The light emitting layer 5 is electrically connected to at least partial region of the conductive shielding layer 4.

The second electrode 6 covers the light emitting layer 5.

The color filter layer 7 is arranged on a side of the second electrode 6 away from the driving backplane 1, and includes at least one light shielding portion 72 and a plurality of light filtering portions 71 separated by the at least one light shielding portion 72. The first electrodes 21 and the light filtering portions 71 are opposite to each other in a direction perpendicular to the driving backplane 1 one to one.

In the display panel according to the embodiment of the present disclosure, any first electrode 21 and its corresponding light emitting layer 5 and the second electrode 6 may constitute a light emitting unit 001. The conductive shielding layer 4 is insulated from the first electrode 21, and the orthographic projection of the conductive shielding layer 4 on the planarization layer 104 is located outside the first electrode 21 and is electrically connected to the light emitting layer 5, and thus the conductive shielding layer 4 can absorb carriers (e.g., holes) generated in the light emitting layer 5 and moving along the distribution direction of the first electrodes 21, and accordingly electric leakage occurring between the light emitting units 001 may be prevented, thereby eliminating cross-color. Also, the at least one separation protrusion 32 of the pixel definition layer 3 can separate the light emitting units 001, and the light emitting layer 5 protrudes at the at least one separation protrusion 32, so that the light emitting layer 5 needs to climb the sidewall of the at least one separation protrusion 32. This is beneficial to make the light emitting layer 5 thin or even disconnected at the at least one separation protrusion 32, and can also prevent mutual leakage between adjacent light emitting units 001 and eliminate cross-color.

The structure for realizing the display function of the display panel of the present disclosure will be described in detail below.

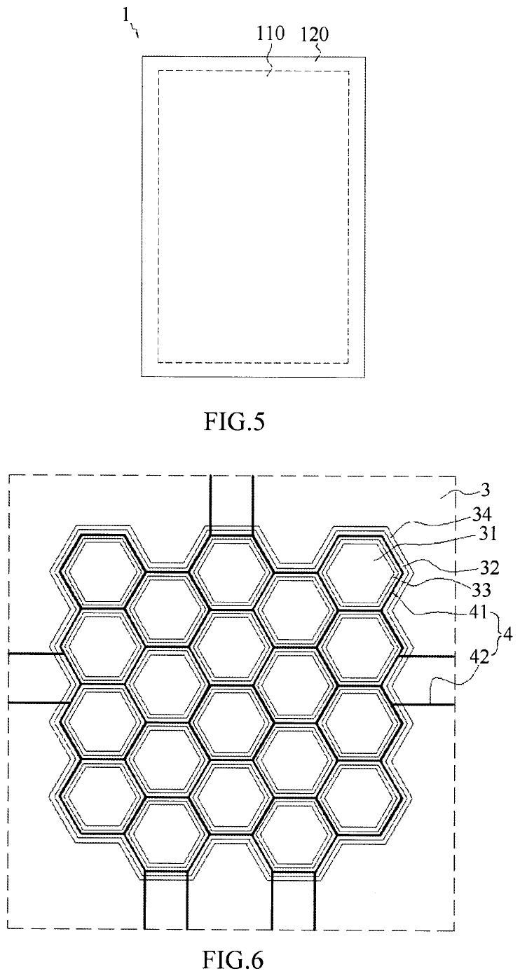

As shown in FIG. 4 and FIG. 5, the driving backplane 1 may include a pixel region 110 and a peripheral region 120. The peripheral region 120 is located outside the pixel region 110 and may be disposed around the pixel region 110. The driving backplane 1 is used to form driving circuits for driving the light emitting unit 001 to emit light, and the driving circuits may include at least one pixel circuit and at least one peripheral circuit.

The number of pixel circuits and light emitting units 001 may be more than one. The pixel circuits are located in the pixel region 110. The pixel circuits may be pixel circuits such as 2T1C, 4T2C, 6T1C, or 7T1C, as long as the pixel circuits can drive the light emitting units 001 to emit light, and embodiments of the present disclosure do not impose specific limitation on the structure of the pixel circuits. The number of the pixel circuits is the same as the number of the first electrodes 21, and the pixel circuits are connected to the first electrodes 21 in a one-to-one correspondence, so as to control the light emitting units 001 to emit light respectively. In the above description, nTmC indicates that a pixel circuit includes n transistors (represented by the letter “T”) and m capacitors (represented by the letter “C”).

The at least one peripheral circuit is located in the peripheral region 120 and is connected to the pixel circuits. The at least one peripheral circuit may include at least one of a light emitting control circuit, a gate 102 driving circuit, a source driving circuit, and a power supply circuit, and of course other circuits may be included, as long as the light emitting units 001 can be driven to emit light through the pixel circuits. Also, the at least one peripheral circuit may include a power supply circuit connected to the second electrode 6 for inputting a power supply signal to the second electrode 6. The at least one peripheral circuit may input driving signals to the first electrodes 21 through the pixel circuits and input the power supply signal to the second electrode, so that the light emitting units 001 can emit light.

In some embodiments of the present disclosure, as shown in FIG. 4, the driving backplane 1 may include a substrate 101, and the substrate 101 may be a silicon substrate. The above-mentioned driving circuits may be formed on the silicon substrate through semiconductor processes. For example, both the pixel circuits and the peripheral circuits may include a plurality of transistors, and a well region 1011 may be formed in the silicon substrate through a doping process, and the well region 1011 has two doped regions 1012 spaced apart each other. Meanwhile, taking a well region 1011 as an example: a gate 102 is provided on a side of the driving backplane 1, that is, the orthographic projection of the gate 102 on the substrate 101 is located between the two doped regions 1012. The driving backplane 1 may further include at least one wiring layer 103 and the planarization layer 104. The at least one wiring layer 103 is arranged on a side of the substrate 101. The planarization layer 104 covers the at least one wiring layer 103. The at least one wiring layer 103 is connected to the doped regions 1012, and includes a source 1031S and a drain 1031D of two doped regions 1012 connected to the same well region 1011.

For example, the at least one wiring layer 103 includes two layers and is located in the planarization layer 104. For example, the at least one wiring layer 103 includes a first wiring layer 1031 and a second wiring layer 1032. The first wiring layer 1031 is arranged on a side of the substrate 101, and a part of the planarization layer 104 is arranged between the substrate 101 and the first wiring layer. The first wiring layer 1031 includes the source 1031S and the drain 1031D. The source 1031S and the drain 1031D of the same transistor are connected to two doped regions 1012 of the same well region 1011, respectively, so that a transistor can be formed by a well region 1011 and its corresponding gate 102, source 1031S and drain 1031D. The second wiring layer 1032 is arranged on a side of the first wiring layer 1031 away from the substrate 101. The second wiring layer 1032 is separated from the first wiring layer 1031 by a part of the planarization layer 104. At least partial regions of the second wiring layer 1032 is connected to the first wiring layer 1031. The transistors are connected through the wiring layers 103 to form driving circuits. The specific connection lines and wiring patterns depend on the circuit structures and are not particularly limited here.

The wiring layers 103 may be formed by a sputtering process. The material of the planarization layer 104 may be silicon oxide, silicon oxynitride or silicon nitride. The planarization layer 104 is formed layer by layer through multiple deposition and polishing processes, that is, the planarization layer 104 may be formed by stacking multiple insulating film layers.

As shown in FIG. 4, the light emitting units 001 of the display panel are arranged in an array on a side of the driving backplane 1. For example, the light emitting units 001 are arranged on a surface of the planarization layer 104 away from the substrate 101. Each light emitting unit 001 may include a first electrode 21, a second electrode 6 and a light emitting layer 5 located between the first electrode 21 and the second electrode 6. Both the first electrode 21 and the second electrode 6 may be connected to the wiring layer 103. By applying driving signals to the first electrodes 21 through the driving backplane 1 and applying the power supply signal to the second electrode 6, the light emitting layer 5 is driven to emit light.

In order to realize color display, it is possible to make the light emitting units 001 emit light of the same color, and by cooperating with the color filter layer 7 located on the side of the second electrode 6 away from the driving backplane 1, color display can be realized. Such display scheme is used as an example. Alternatively, each light emitting unit 001 can also be made to emit light independently, and the light emitting colors of different light emitting units 001 can be different.

In some embodiments of the present disclosure, as shown in FIGS. 4 and 6, a plurality of light emitting units 001 may be formed by the first electrode layer 2, the pixel definition layer 3, the light emitting layer 5 and the second electrode 6.

The first electrode layer 2 is arranged on a side of the driving backplane 1. For example, the first electrode layer 2 is arranged on the surface of the planarization layer 104 away from the substrate 101. The first electrode layer 2 may include a plurality of first electrodes 21 distributed with space between them. The orthographic projection of each first electrode 21 on the driving backplane 1 is located in the pixel region 110a. Each first electrode 21 is connected to a pixel circuit. One of the first electrodes 21 may be connected with one pixel circuit. For example, the first electrodes 21 may be connected to the second wiring layer 1032.

The first electrode layer 2 may have a single-layer or multi-layer structure, and its material is not particularly limited herein. For example, the first electrode layer 2 may include a first layer 201, a second layer 202, a third layer 203 and a fourth layer 204 which are sequentially stacked in a direction away from the driving backplane 1. The first layer 201 and the third layer 203 may use the same metal material, such as titanium. The fourth layer 204 may use a transparent conductive material such as ITO (indium tin oxide). The second layer 202 may use a metal material that is different from the materials of the first layer 201, the second layer 202 and the fourth layer 204, and has a resistivity lower than the first layer 201, the second layer 202 and the fourth layer 204. For example, the material of the third layer 203 may be aluminum.

As shown in FIG. 4 and FIG. 6, the pixel definition layer 3 and the first electrode layer 2 are arranged on the same surface of the driving backplane 1, that is, the surface of the planarization layer 104 away from the substrate 101. The pixel definition layer 3 exposes each of the first electrodes 21. Specifically, the pixel definition layer 3 is provided with openings 31 exposing the first electrodes 21. The range of each light emitting unit 001 can be defined by the pixel definition layer 3 and an opening 31. The material of the pixel definition layer 3 may be insulating materials such as silicon oxide or silicon nitride, which are not particularly limited herein.

The orthographic projection of any opening 31 on the driving backplane 1 is located within the first electrode 21 exposed by the opening 31, that is, the opening 31 is not larger than the exposed first electrode 21. In some embodiments of the present disclosure, the pixel definition layer 3 has at least one extension portion 33. The at least one extension portion 33 is located on the surface of the first electrode 21 away from the driving backplane 1 and covers the edge of the first electrode 21. The opening 31 is provided in an extension portion 33, so that the extension portion 33 is an annular structure with an opening 31. As shown in FIG. 6, the shape of the opening 31 may be a polygon such as a rectangle, a pentagon, and a hexagon, but not necessarily a regular polygon. The shape of the opening 31 may also be other shapes such as an ellipse, and embodiments of the present disclosure do not impose specific limitations on this.

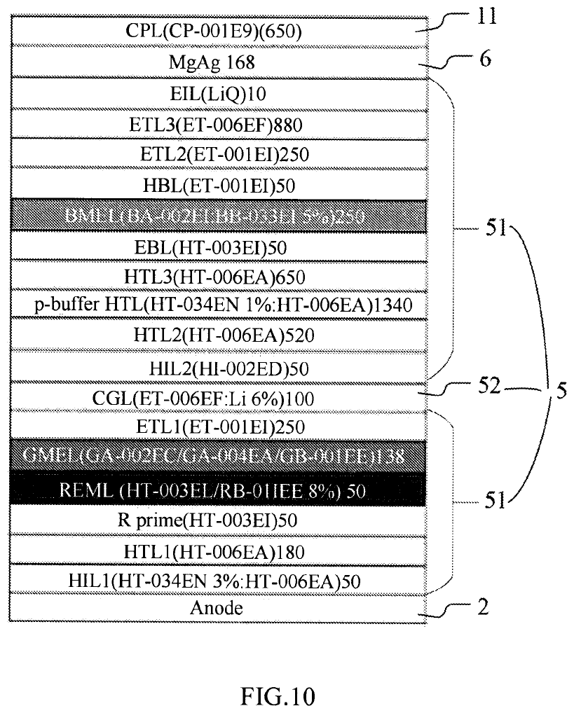

As shown in FIG. 4 and FIG. 10, the light emitting layer 5 covers the pixel definition layer 3 and the first electrodes 21. The light emitting layer 5 is located in an opening 31 and a region where the light emitting layer 5 overlaps with the first electrode layer 2 is used for forming the light emitting unit 001. That is, the light emitting units 001 may share the same light emitting layer 5. In other words, the parts of the light emitting layer 5 located in different openings 31 belong to different light emitting units 001. In addition, since the light emitting units 001 share the light emitting layer 5, the light emitting colors of different light emitting units 001 are the same.

In some embodiments of the present disclosure, as shown in FIG. 10, the light emitting unit 001 may include a plurality of light emitting devices, each of which includes a first electrode 21, a second electrode 6, and plurality of light emitting sub-layers 51 between the first electrode 21 and the second electrode 6. The light emitting devices of the same light emitting unit 001 may share the same first electrode 21 and the same second electrode 6, that is, the same light emitting unit 001 may have only one first electrode 21 and one second electrode 6.

For example, as shown in FIG. 10, the light emitting layer 5 may include a plurality of light emitting sub-layers 51 serially connected in sequence along the direction away from the driving backplane 1. At least one light emitting sub-layer 51 is connected in series with an adjacent light emitting sub-layer 51 through a charge generation layer 52. When applying electrical signals to the first electrode 21 and the second electrode 6, each light emitting sub-layer 51 can emit light, and different light emitting sub-layers 51 can be used to emit light of different colors.

Further, as shown in FIG. 10, any one of the light emitting sub-layers 51 may include a hole injection layer (HIL), a hole transport layer (HTL), a light emitting material layer (EL), an electron transport layer (ETL) and an electron injection layer (EIL). The specific light emitting principle will not be described in detail here, and the number of the hole injection layer(s), the hole transport layer(s), the electron transport layer(s) and electron injection layer(s) is not specifically limited here. The light emitting sub-layers 51 may share one or more of the hole injection layer, the hole transport layer, the electron transport layer, and the electron injection layer. Meanwhile, the charge generation layer 52 may be provided between at least two adjacent light emitting sub-layers 51, so that the two light emitting sub-layers 51 are connected in series.

In some embodiments of the present disclosure, as shown in FIG. 10, the light emitting layer 5 may include three light emitting sub-layers 51 with different colors, namely, a first light emitting sub-layer 51 that emits red light, a second light emitting sub-layer 51 that emits green light, and a third light emitting sub-layer 51 that emits blue light. When the first light emitting sub-layer 51, the second light emitting sub-layer 51 and the third light emitting sub-layer 51 emit light simultaneously, the light emitting layer 5 can emit white light. The first light emitting sub-layer 51 and the second light emitting sub-layer 51 share a hole injection layer, a hole transport layer, an electron transport layer and an electron injection layer, and the light emitting material layer of the second light emitting sub-layer 51 is arranged on a surface of the light emitting material layer of the first light emitting sub-layer 51 away from the driving backplane 1, so that the first light emitting sub-layer 51 and the second light emitting sub-layer 51 are directly connected in series. A surface of the second light emitting sub-layer 51 away from the driving backplane 1 may be provided with the charge generation layer 52. The third light emitting sub-layer 51 shares an electron injection layer with the first light emitting sub-layer 51 and the second light emitting sub-layer 51, and the hole injection layer of the third light emitting sub-layer 51 is arranged on a surface of the charge generation layer 52 away from the driving backplane 1, and thus the third light emitting sub-layer 51 and the second light emitting sub-layer 51 may be connected in series.

As shown in FIG. 4, the second electrode 6 covers the light emitting layer 5, and the orthographic projection of the second electrode 6 on the driving backplane 1 can cover the pixel region 110 and extend into the peripheral region 120. The light emitting units 001 may share the same second electrode 6. When a voltage difference between the second electrode 6 and the first electrodes 21 reaches a voltage difference that enables the light emitting layer 5 to emit light, the light emitting layer 5 can emit light. The voltages of the power supply signal input to the second electrode 6 and the driving signals input to the first electrodes 21 may be controlled to control the light emitting layer 5 to emit light.

As shown in FIG. 4, the color filter layer 7 is arranged on the side of the second electrode 6 away from the driving backplane 1, and includes a plurality of light filtering portions 71. The first electrodes 21 and the light filtering portions 71 are opposite to each other one to one in the direction perpendicular to the substrate 101, that is, the orthographic projection of a light filtering portion 71 on the planarization layer 104 at least partially overlaps with a first electrode 21. The light filtering portions 71 include at least three colored light filtering portions 71, for example, a light filtering portion 71 that transmits red light, a light filtering portion 71 that transmits green light, and a light filtering portion 71 that transmits blue light. After the light emitted by the light emitting units 001 is filtered by the light filtering portions 71, monochromatic light of different colors can be obtained, thereby realizing color display. A light filtering portion 71 and its corresponding light emitting unit 001 may constitute a sub-pixel. The color of the light emitted by any one sub-pixel is the color of light which passes through its light filtering portion 71. A plurality of sub-pixels may constitute a pixel, and the light emitting colors of the sub-pixels of the same pixel are different.

The shape of the orthographic projection of each light filtering portion 71 on the planarization layer 104 may be the same as the shape of each opening 31 of the pixel definition layer 3. The orthographic projections of the openings 31 on the planarization layer 104 are located within the orthographic projections of the light filtering portions 71 on the planarization layer 104 in a one-to-one correspondence.

As shown in FIG. 4, the color filter layer 7 may further include at least one light shielding portion 72 which separates the light filtering portions 71. The light shielding portion 72 does not transmit light and shields the area between two light emitting units 001. A light filtering portion 71 may be directly spaced from another light filtering portion 71 by using a light-shielding material; or, in some embodiments of the present disclosure, adjacent light filtering portions 71 may be stacked in a region corresponding to two adjacent light emitting units 001, and the colors of the light transmitted by the two light filtering portions are different, so that light cannot pass through the stacked region.

In addition, in some embodiments of the present disclosure, on the basis that the light emitting layer 5 emits white light, in order to improve the brightness of images, the color filter layer 7 may further include a transparent portion. In the direction perpendicular to the substrate 101, a transparent portion may be arranged opposite to a light emitting unit 001, so that the color filter layer 7 can also transmit white light, and can increase the brightness through the white light.

In order to improve the light extraction efficiency, a light extraction layer 11 may be covered on a side of the second electrode 6 away from the driving backplane 1 to improve the brightness. Further, the light extraction layer 11 may directly cover the surface of the second electrode 6 away from the driving backplane 1.

In order to facilitate the connection of the second electrode 6 with the driving circuit, in some embodiments of the present disclosure, the first electrode layer 2 further includes an interconnection ring. The orthographic projection of the interconnection ring on the driving backplane 1 is located in the peripheral region 120. The interconnection ring can be connected to the peripheral circuit and surround the pixel region 110. The second electrode 6 may be connected with the interconnection ring, and accordingly the second electrode 6 may be connected with the peripheral circuit through the interconnection ring, so that the driving signal may be applied to the second electrode 6 by the peripheral circuit. The pattern of the interconnection ring may be the same as the pattern of the first electrode 21 in the pixel region 110, so as to improve the uniformity of the pattern of the first electrode layer 2.

As shown in FIG. 4, in some embodiments of the present disclosure, the display panel of the present disclosure may further include a first encapsulation layer 8, which may be arranged on the side of the second electrode 6 away from the driving backplane 1 and located between the color filter layer 7 and the second electrode 6 to block the erosion of external water and oxygen. The first encapsulation layer 8 may be a single-layer or multi-layer structure. For example, the first encapsulation layer 8 may include a first encapsulation sub-layer 81, a second encapsulation sub-layer 82 and a third encapsulation sub-layer 81 which are sequentially stacked in the direction away from the driving backplane 1. The materials of the first encapsulation sub-layer 81 and the second encapsulation sub-layer 82 may be inorganic insulating materials such as silicon nitride or silicon oxide, and the second encapsulation sub-layer 82 may adopt an Atomic Layer Deposition (ALD) process. The material of the third package sub-layer 83 may be an organic material, which may be formed by a Molecular Layer Deposition (MLD) process. Of course, the first encapsulation layer 8 may also adopt other structures, and the structure of the first encapsulation layer 8 is not particularly limited herein.

In addition, in some embodiments of the present disclosure, the display panel of the present disclosure may further include a transparent cover plate 10, which may cover the side of the color filter layer 7 away from the driving backplane 1. The transparent cover plate 10 may be a single-layer or multi-layer structure, and the material of the transparent is not particularly limited here.

In some embodiments of the present disclosure, the display panel may further include a second encapsulation layer 9, which may cover the surface of the color filter layer 7 away from the driving backplane 1, so as to achieve planarization and cover the transparent cover plate 10, and improve the encapsulation effect to further block water and oxygen. The second encapsulation layer 9 may have a single-layer or multi-layer structure, and may include inorganic materials such as silicon nitride or silicon oxide, or may include organic materials, and the structure of the second encapsulation layer 9 is not particularly limited herein.

The solution of the display panel of the present disclosure for solving the problem of cross-color will be described in detail below.

Combined with the above analysis of the related art, light emitting units 001 share the light emitting layer 5, the carriers (for example, holes) of one light emitting unit 001 may move to other light emitting units 001 through film layers such as the charge generation layer 52, especially move to an adjacent light emitting unit 001, and in this case leakage occurs, which affects the purity of light emission. To this end, as shown in FIG. 4, a conductive shielding layer 4 can be provided between the planarization layer 104 and the light emitting layer 5, and the conductive shielding layer is located between two adjacent light emitting units 001. The conductive shielding layer 4 is insulated from the first electrodes 21, but is conductive. The carriers can be absorbed by the conductive shielding layer 4 to prevent the carriers from moving between the light emitting units 001, thereby avoiding cross-color caused by the leakage.

As shown in FIG. 4, the conductive shielding layer 4 may be a single-layer or multi-layer structure. For example, in some embodiments of the present disclosure, the conductive shielding layer 4 includes a first conductive layer 401, a second conductive layer 402 and a third conductive layer 403 which are sequentially stacked in the direction away from the substrate 101. The materials of the first conductive layer 401 and the third conductive layer 403 may be the same as the first layer 201 and the third layer 203 of the first electrode layer 2. For example, the materials of the first conductive layer 401 and the third conductive layer 403 are both metal titanium. The material of the second conductive layer 402 may be the same as the material of the second layer 202 of the first electrode layer 2. For example, the material of the second conductive layer 402 is metal aluminum. Therefore, the conductive shielding layer 4 can be formed by at least part of the processes of forming the first electrode layer 2, so as to save costs, and also the conductivity of the conductive shielding layer 4 can be made similar to that of the first electrode layer 2, so as to avoid absorbed carriers too much or too little to affect normal lighting.

As shown in FIGS. 4 and 6, in some embodiments of the present disclosure, at least one separation protrusion 32 may be formed in the pixel definition layer 3 in regions outside the light emitting units 001, i.e., the regions other than the openings 31. The at least one separation protrusion 32 may protrude in the direction away from the substrate 101, so that the light emitting layer 5 is raised at the separation protrusion 32. The light emitting layer 5 needs to climb the side wall of the separation protrusion 32. This is beneficial to make the charge generation layer 52 and at least a part of the light emitting sub-layers 51 in the light emitting layer 5 become thin and even disconnected, and thus electric leakage may be further prevented. Meanwhile, the conductive shielding layer 4 covers at least partial region of the at least one separation protrusion 32, for example, at least part of the conductive shielding layer 4 is stacked on the top surface of the at least one separation protrusion 32. The top surface is a surface of the separation protrusion 32 away from the driving backplane 1. The area of the orthographic projection of the conductive shielding layer 4 on the top surface of the separation protrusion 32 is smaller than the area of the top surface of the separation protrusion 32, that is, the conductive shielding layer 4 does not completely cover the top surface of the separation protrusion 32.

The pixel definition layer 3 having the at least one separation protrusion 32 may be formed through multiple deposition and etching processes, or the pixel definition layer 3 may also be formed through a grayscale mask process, and the formation processes of the pixel definition layer 3 are not particularly limited herein.

In some embodiments of the present disclosure, the conductive shielding layer 4 may be arranged on the surface of the pixel definition layer 3 away from the substrate 101 and cover at least partial region of the at least one separation protrusion 32. For example, the conductive shielding layer 4 is located on the surface of the at least one separation protrusion 32 away from the substrate 101. The light emitting layer 5 may cover the conductive shielding layer 4 and be in direct contact with the conductive shielding layer 4, so as to electrically connect the conductive shielding layer 4 and the light emitting layer 5.

In order to avoid electric leakage to the greatest extent, the light emitting units 001 may be surrounded by the conductive shielding layer 4 and the at least one separation protrusion 32. For example, as shown in FIGS. 4 and 6, in some embodiments of the present disclosure, the at least one separation protrusion 32 includes at least one annular separation ring 321. One annular separation ring 321 surrounds outside of one first electrode 21. Correspondingly, the conductive shielding layer 4 may include at least one shielding ring 41. One shielding ring 41 may be stacked on the top surface of one separation ring 321. A first electrode 21 may be surrounded by the separation ring 321 and the shielding ring 41 on the separation ring 321, that is, a light emitting unit 001 can be surrounded. In addition, the shielding rings 41 may be connected to the second electrode 6, so as to export the carriers absorbed by the conductive shielding layer 4, and thus it is difficult for the light emitting unit 001 to leak electricity to an adjacent light emitting unit 001.

Further, as shown in FIG. 6, the at least one separation protrusion 32 may include a plurality of separation rings 321, and the conductive shielding layer 4 may include a plurality of shield rings 41, and the number of the separation rings 321 and the shield rings 41 may be the same as the number of the first electrodes 21. Similarly, a shielding ring 41 is stacked on a corresponding separation ring 321, and the shielding ring 41 and the separation ring 321 can be concentrically arranged in a ring structure. Each separation ring 321 and the shielding ring 41 therein can surround a first electrode 21.

In order to facilitate the export of the carriers absorbed by the conductive shielding layer 4, the conductive shielding layer 4 can be connected to a peripheral circuit. Also, a power supply signal may be input to the conductive shielding layer 4. The voltage difference between the power supply signal and the power supply signal input to the second electrode 6 is smaller than the turn-on voltage difference that enables the light emitting layer 5 to emit light, thereby avoiding the light emitting layer 5 between the conductive shielding layer 4 and the second electrode 6 to emit light, while only the light emitting layer 5 between the first electrodes 21 and the second electrode 6 emits light. For example, the conductive shielding layer 4 may be electrically connected to the second electrode 6. Although the light emitting layer 5 also exists between the conductive shielding layer 4 and the second electrode 6, the potentials of the conductive shield layer 4 and the second electrode 6 are the same and the voltage difference is zero and thus the light emitting layer 5 will not be driven to emit light, because the conductive shielding layer 4 and the second electrode 6 are electrically connected. Of course, the conductive shielding layer 4 can also be directly grounded through the peripheral circuit, or connected to other signals, as long as the carriers can be exported to avoid electric leakage between adjacent light emitting units 001 and the light emitting layer 5 will not emit light in the region corresponding to the conductive shielding layer 4.

The way in which the conductive shielding layer 4 is electrically connected to the second electrode 6 will be described in detail below.

As shown in FIG. 6, in some embodiments of the present disclosure, the at least one shielding ring 41 may be electrically connected to the second electrode 6. Specifically, the at least one shielding ring 41 may be connected into an integral structure. Correspondingly, the at least one separation ring 321 of the at least one separation protrusion 32 may be connected to form an integral structure. For example, the conductive shielding layer 4 may further include at least one connection body 42. The orthographic projection of the at least one connection body 42 on the driving backplane 1 extends from the pixel region 110 to the peripheral region 120. The at least one connection body 42 is connected to at least one shielding ring 41, and is connected to the second electrode 6 in a region corresponding to the peripheral region 120. The number of the at least one connection body 42 may be more than one, and the connection bodies may be distributed around the pixel region 110. Each connection body 42 may be connected to a shielding ring 41. Because the shielding rings 41 are connected as an integral structure, each connection body 42 is electrically connected to the shielding rings 41. The structure of the connection body 42 may be a wire or the like, which is not particularly limited here, as long as the connection body can play a role of conductive connection.

Further, the orthographic projection of the light emitting layer 5 on the driving backplane 1 covers the pixel region 110 and extends into the peripheral region 120, and has a certain distance from the boundary of the peripheral region 120. The boundary of the orthographic projection of the second electrode 6 on the substrate 101 is located outside the boundary of the orthographic projection of the light emitting layer 5 on the substrate 101. The connection body 42 may extend outside the boundary of the light emitting layer 5, and may be in direct contact with a region of the second electrode 6 outside the boundary of the light emitting layer 5, so that the second electrode 6 is connected to the shielding ring 41 through the connection body 42.

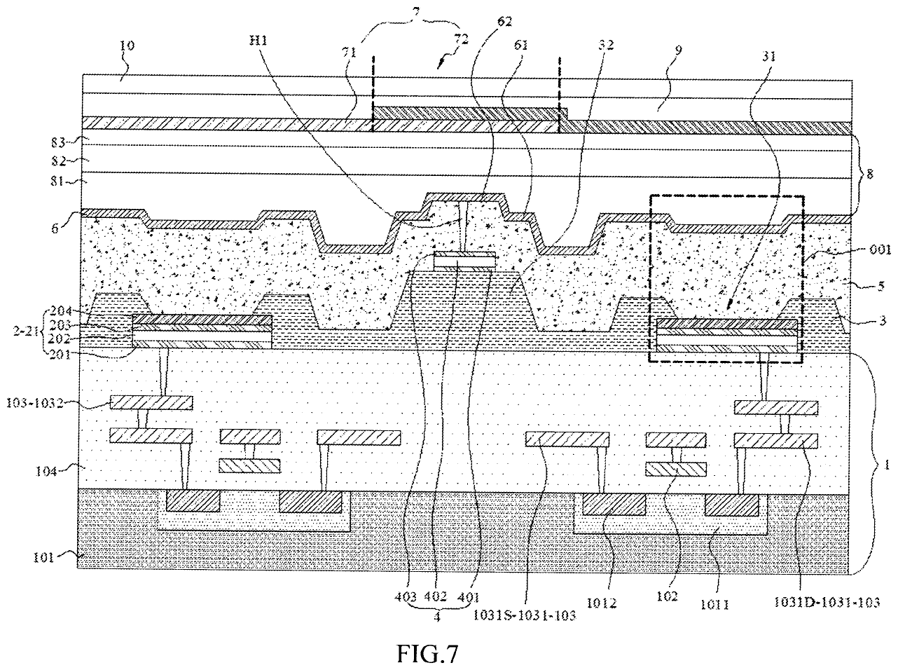

As shown in FIG. 7, in some other embodiments of the present disclosure, the shielding rings 41 are located on the surface of the pixel definition layer 3 away from the substrate 101, and at least a part of the shielding rings 41 may be connected to the second electrode 6 through a first via hole H1 passing through the light emitting layer 5. The orthographic projection of at least one first via hole H1 on the planarization layer 104 is located between two adjacent first electrodes 21. If the shielding rings 41 are formed as an integral structure, one shielding ring 41 is at least required to be connected to the second electrode 6. Alternatively, a plurality of first via holes 401 may be provided to connect the plurality of shielding rings 41 with the second electrode 6, and the first via holes 401 may be used for connecting each of the plurality of shielding rings 41 with the second electrode. The orthographic projection of each first via hole 401 on the driving backplane 1 is located in the pixel region 110.

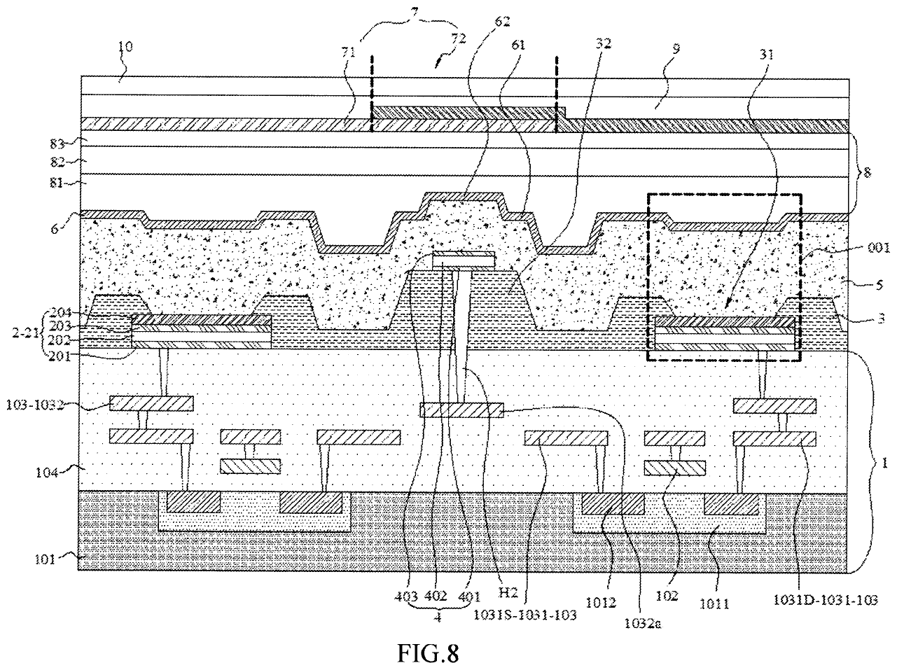

As shown in FIG. 8, in another embodiment of the present disclosure, at least one wiring layer 103 may include a connection portion 1032a. For example, the second wiring layer 1032 may include a connection portion 1032a. The potential of the connection portion 1032a may be the same as that of the second electrode 6. For example, the connection portion 1032a may extend to the peripheral region 120 and be connected to the second electrode 6. A signal with a potential the same as the potential of the power supply signal input to the second electrode may be input to the connection portion 1032a. Meanwhile, if the conductive shielding layer 4 is located on the side of the pixel definition layer 3 away from the substrate 101, the planarization layer 104 and the pixel definition layer 3 may be provided with a second via hole H2 connected to the connection portion 1032 a, and the second via hole H2 may be connected to a shielding ring 41 to connect the shielding ring 41 to the second electrode 6. Alternatively, the potential of at least one shielding ring 41 and the second electrode 6 can be made equal, thereby preventing the light emitting layer 5 between the shielding ring 41 and the second electrode 6 to emit light. If the conductive shielding layer 4 is located on the surface of the planarization layer 104 away from the substrate 101, the second via hole H2 is located in the planarization layer 104.

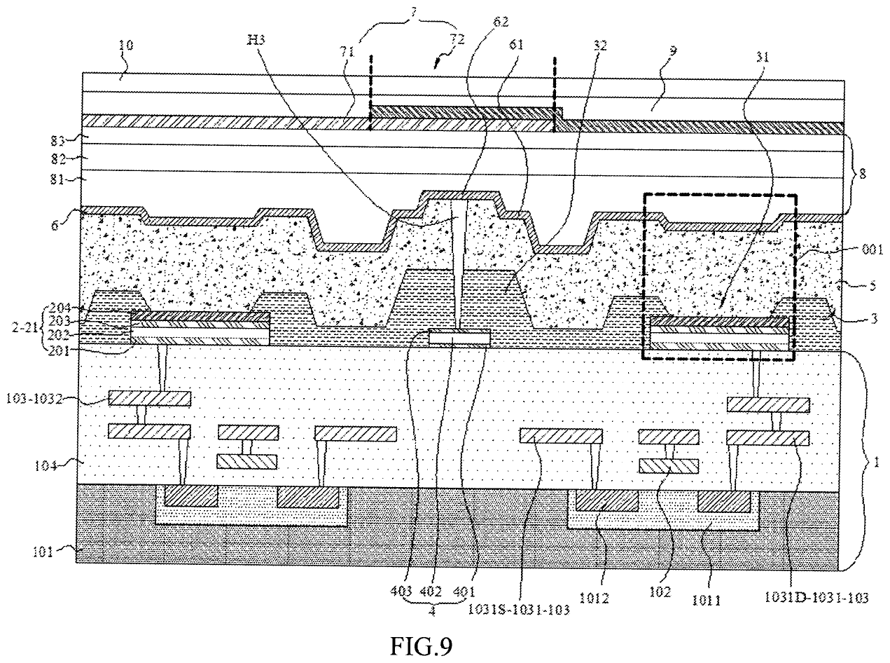

As shown in FIG. 9, in still some other embodiments of the present disclosure, the at least one shielding ring 41 is located on the surface of the planarization layer 104 away from the substrate 101 and is covered by the pixel definition layer 3. The second electrode 6 and the at least one shielding ring 41 may be electrically connected through a third via hole H penetrating the light emitting layer 5 and the pixel definition layer 3.

Further, due to the existence of the at least one separation protrusion 32, the light emitting layer 5 protrudes at the separation protrusion 32, and correspondingly, the second electrodes 6 also protrude at the at least one separation protrusion 32 to form a first protruding region 61. Meanwhile, since at least partial region of the at least one the separation protrusion 32 is covered by the conductive shielding layer 4, the light emitting layer 5 protrudes in the region corresponding to the conductive shielding layer 4. Correspondingly, a region of the top surface of the first protruding region 61 corresponding to the conductive shielding layer 4 protrudes in a direction away from the conductive shielding layer 4 to form a second protruding region 62.

In addition, the pixel definition layer 3 has a groove 34 between a separation protrusion 32 and an adjacent extension portion 33, which is beneficial to make the charge generation layer 52 and at least part of the light emitting sub-layers 51 in the light emitting layer 5 become thin and even disconnected, thereby further preventing cross-color.

The effects of the display panel of the present disclosure are described below.

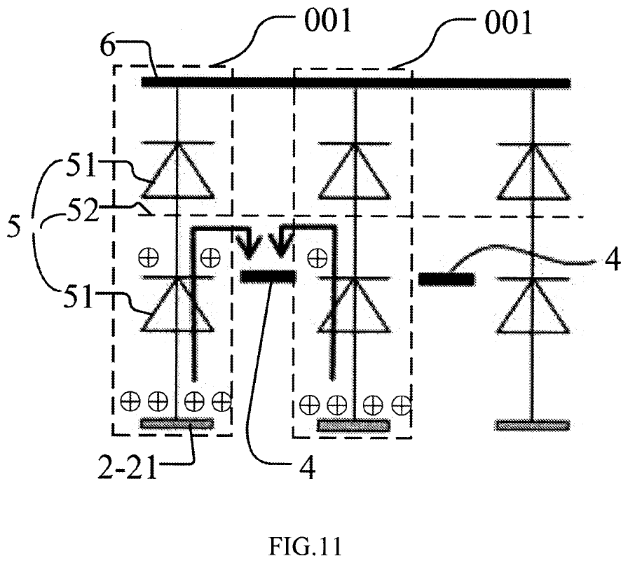

FIG. 11 shows the circuit principle of the conductive shielding layer 4 absorbing carriers. It can be seen that the carriers (holes) between two adjacent light emitting units 001 are absorbed by the conductive shielding layer 4, and thus electric leakage between the two light emitting units 001 is avoided.

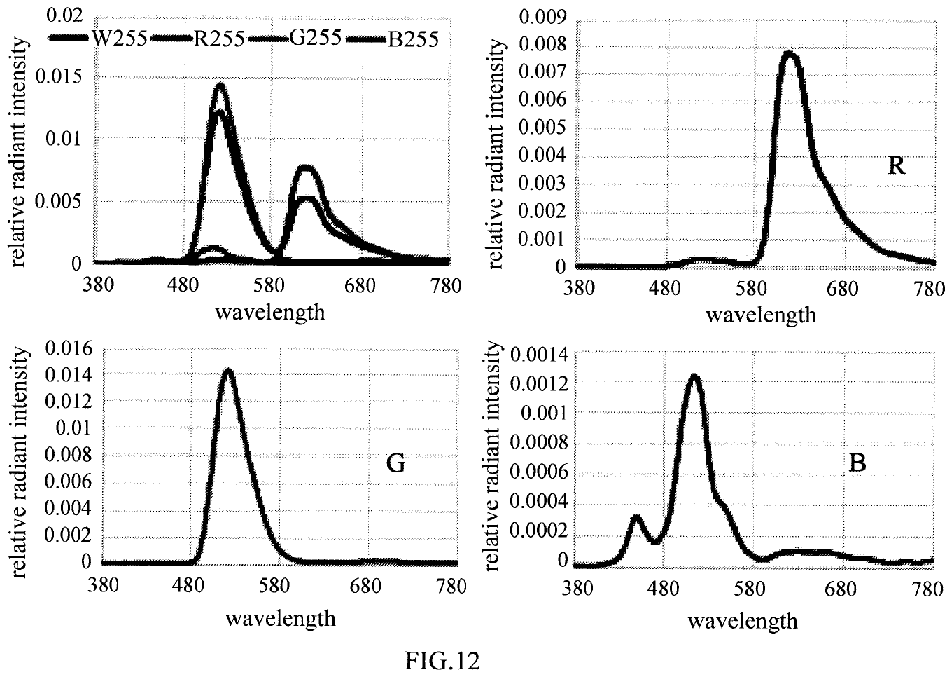

FIG. 12 shows a spectrogram when three sub-pixels (i.e., the red (R), green (G), and blue (B) sub-pixels) are turned on at the same time and a spectrogram when three sub-pixels (i.e., the red (R), green (G), and blue (B) sub-pixels) are turned on separately. Compared with the spectrograms of the related art shown in FIG. 3, it can be seen that in the display panel of the present disclosure, when the three sub-pixels are turned on separately, the light of different colors is obviously reduced, so that the color gamut of the entire display panel is improved. According to calculations, the color gamut index (NTSC) of the display panel can reach 80%.

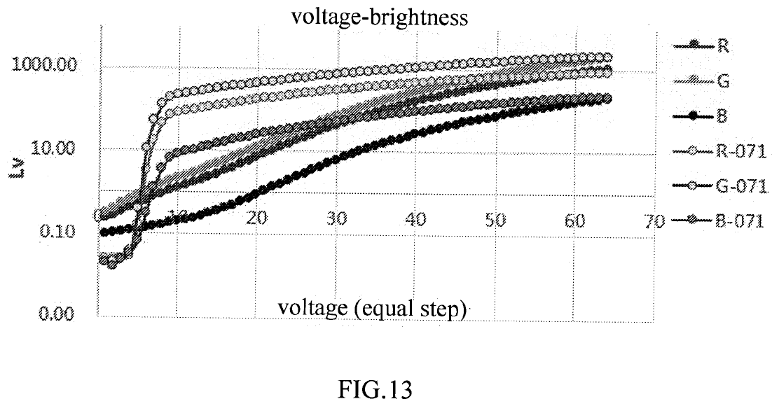

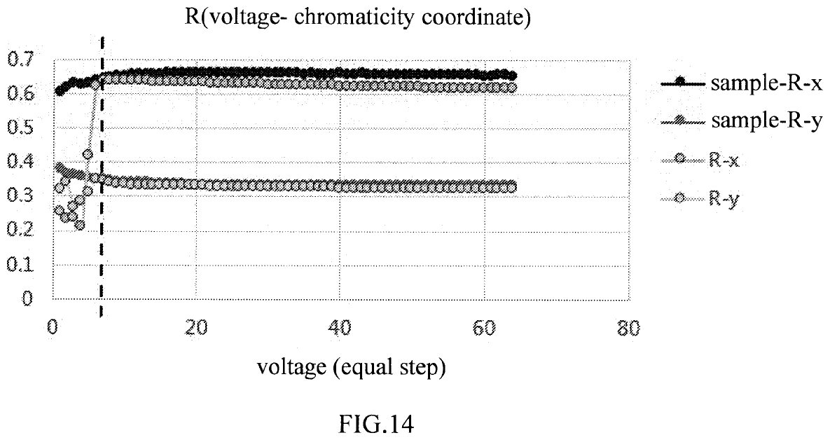

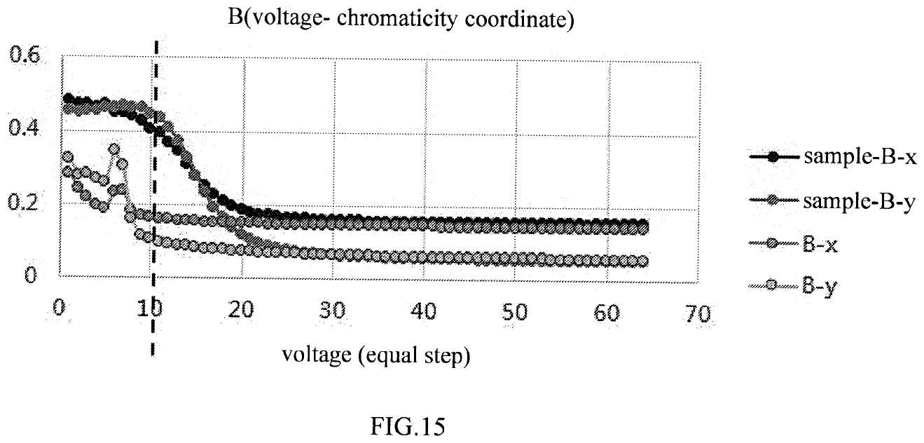

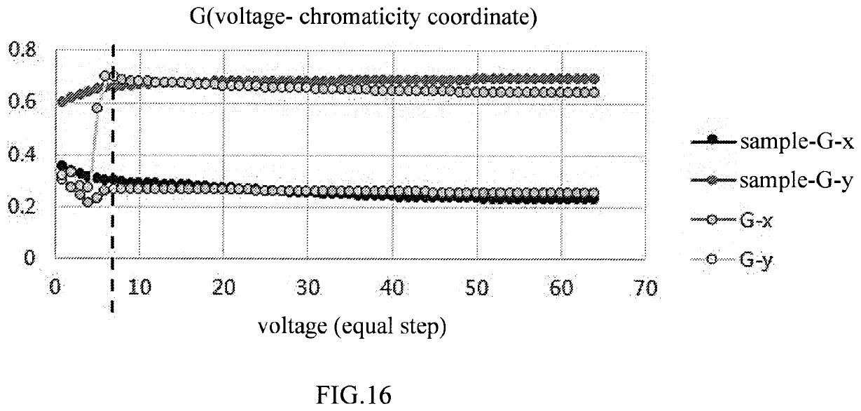

FIG. 13 shows the voltage-brightness curves of red (R), green (G), and blue (B) sub-pixels. The R, G, and B curves are the curves for three sub-pixels according to an embodiment of the present disclosure, R-071, G-071 and B-071 are the curves for three sub-pixels in the related art. FIG. 14 to FIG. 16 respectively show the voltage-chromaticity coordinate curves for three sub-pixels (red (R), green (G) and blue (B)). Sample-R-x, sample-R-y, sample-G-x, sample-G-y, sample-B-x and sample-B-y curves are chromaticity coordinate curves for three sub-pixels in an embodiment of the disclosure; R-x, R-y, G-x, G-y, B-x and B-y curves are chromaticity coordinate curves for three sub-pixels in the related art.

It can be seen from FIG. 14 to FIG. 16 that the display panel in the related art has obvious brightness and chromaticity coordinate changes under low voltage (the left side of the dashed line), and the voltage changes are accompanied by jumping and inversion problems, which makes the Gamma debug under low gray scale become difficult, and the display panel is more prone to color bar problems. In the display panel according to the embodiment of the present disclosure, the amplitude of change of each monochromatic chromaticity coordinate as the voltage changes is significantly reduced, which is beneficial to Gamma debug, and the transitions of curves are smooth without jumping problems.

To sum up, it can be seen that some embodiments of the display panel of the present disclosure can prevent the electric leakage, thereby avoiding the problem of color-cross.

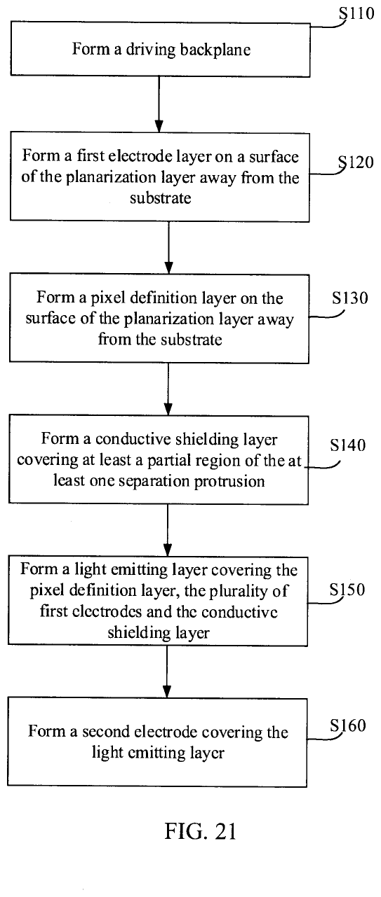

An embodiment of the present disclosure further provides a method for manufacturing a display panel, as shown in FIG. 21. The display panel may be the display panel of any of the above-mentioned embodiments. As shown in FIG. 4 and FIGS. 17 to 21, the manufacturing method may include steps S110 to S170.

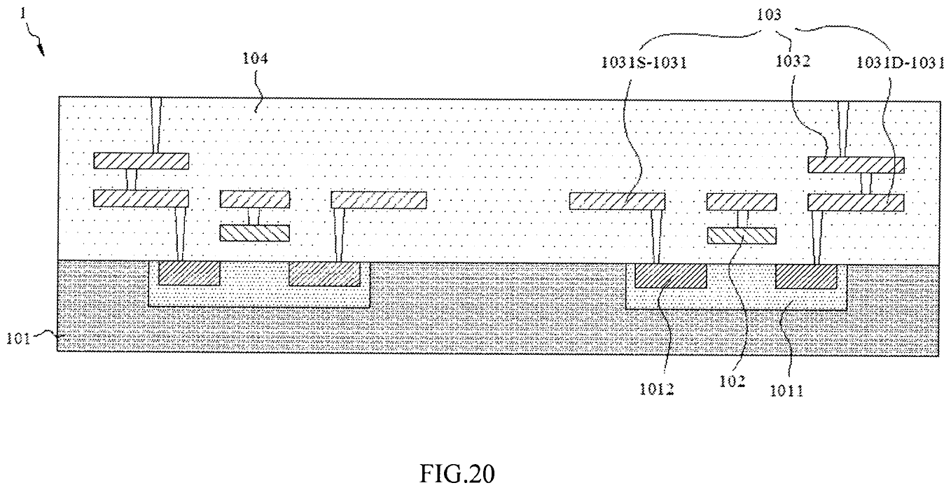

In step S110, a driving backplane is formed. The driving backplane includes a substrate, at least one wiring layer and a planarization layer, the at least one wiring layer is arranged on a side of the substrate, and the planarization layer covers the at least one wiring layer, as shown in FIG. 20.

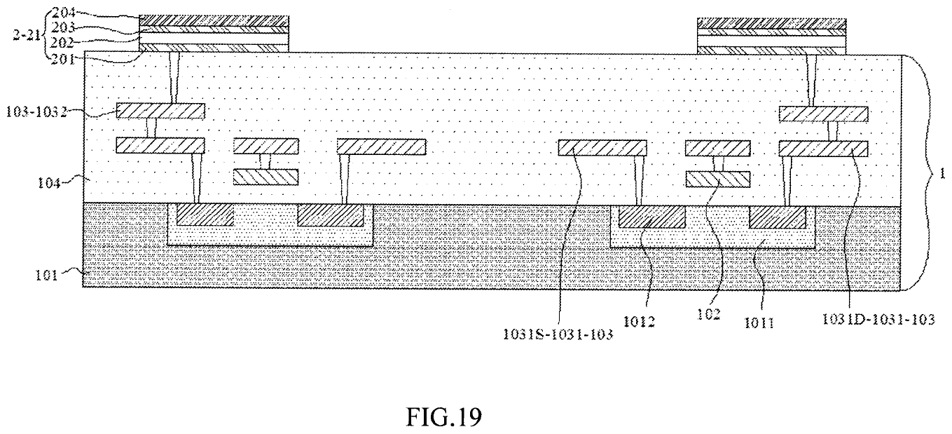

In step S120, a first electrode layer is formed on a surface of the planarization layer away from the substrate. The first electrode layer includes a plurality of first electrodes spaced apart from each other, as shown in FIG. 19.

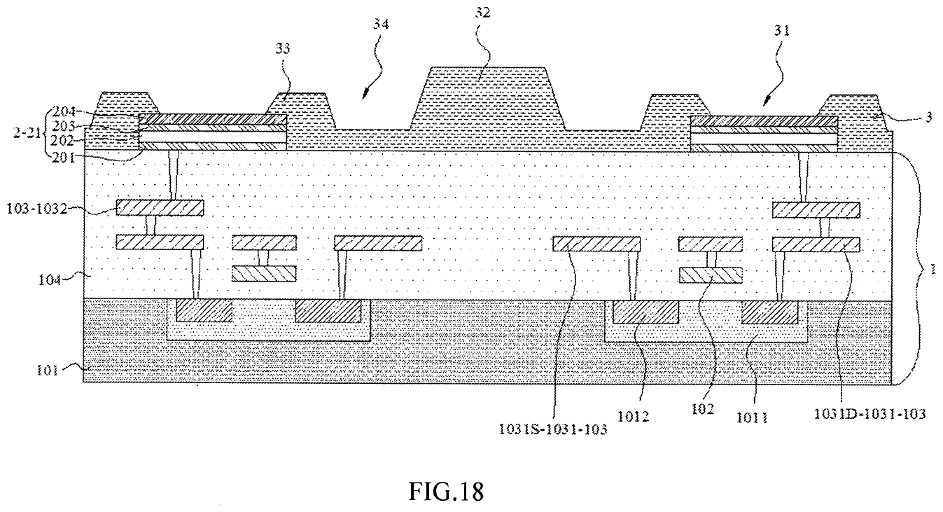

In step S130, a pixel definition layer is formed on the surface of the planarization layer away from the substrate. The pixel definition layer exposes each of the plurality of first electrodes, the pixel definition layer is provided with at least one separation protrusion which is raised along a direction away from the substrate, and an orthographic projection of the at least one separation protrusion on the planarization layer is located outside the first electrodes, as shown in FIG. 18.

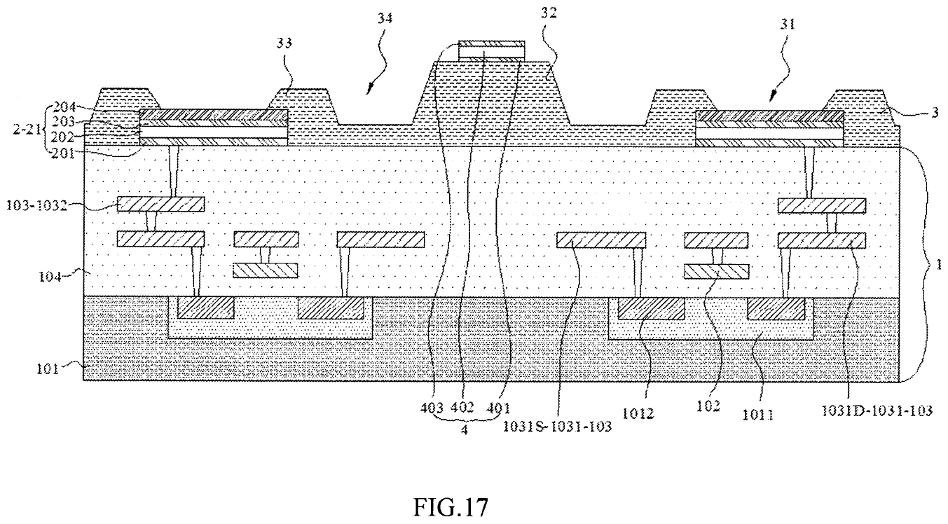

In step S140, a conductive shielding layer covering at least a partial region of the at least one separation protrusion is formed, as shown in FIG. 17.

In step S150, a light emitting layer covering the pixel definition layer, the plurality of first electrodes and the conductive shielding layer is formed. The light emitting layer protrudes at the at least one separation protrusion, and the light emitting layer is in direct contact with the conductive shielding layer, as shown in FIG. 4.

In step S160, a second electrode covering the light emitting layer is formed, as shown in FIG. 14.

In some embodiments of the present disclosure, step S110 includes step S1110 and step S1120.

In step S1110, a substrate is formed.

In step S1120, at least one wiring layer and a planarization layer covering the at least one wiring layer are formed on a side of the substrate. The first electrode layer is arranged on the surface of the planarization layer away from the substrate.

In addition, the manufacturing method according to an embodiment of the present disclosure may further include step S170.

In step S170, a color filter layer including a plurality of light filtering portions is formed on the side of the second electrode away from the substrate. The first electrodes and the light filtering portions are opposite to each other one to one in a direction perpendicular to the substrate, as shown in FIG. 4.

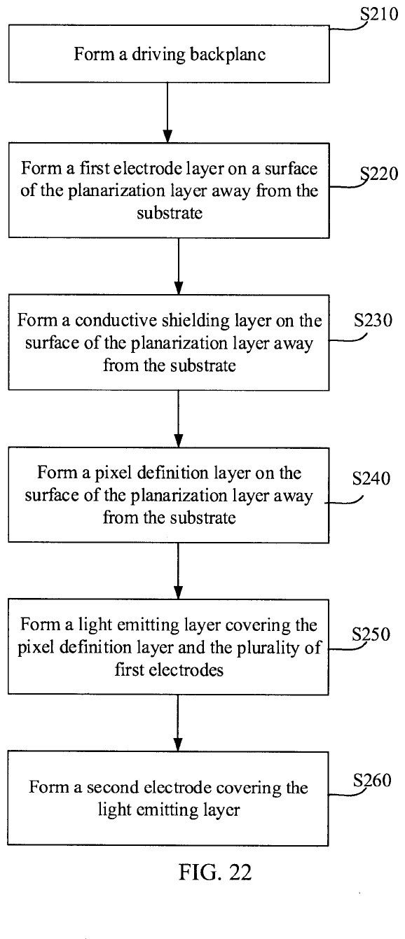

An embodiment of the present disclosure also provides a method for manufacturing a display panel, as shown in FIG. 22. The display panel may be the display panel of any of the above-mentioned embodiments. As shown in FIG. 9 and FIG. 22, the manufacturing method may include steps S210 to S270.

In step S210, a driving backplane is formed. The driving backplane includes a substrate, at least one wiring layer and a planarization layer, the at least one wiring layer is arranged on a side of the substrate, and the planarization layer covers the at least one wiring layer.

In step S220, a first electrode layer is formed on a surface of the planarization layer away from the substrate. The first electrode layer includes a plurality of first electrodes spaced apart from each other.

In step S230, a conductive shielding layer is formed on the surface of the planarization layer away from the substrate, wherein the conductive shielding layer is spaced apart from the first electrodes.

In step S240, a pixel definition layer is formed on the surface of the planarization layer away from the substrate. The pixel definition layer exposes each of the plurality of first electrodes, the pixel definition layer is provided with at least one separation protrusion which is raised along a direction away from the substrate, and an orthographic projection of the at least one separation protrusion on the planarization layer is located outside the first electrodes.

In step S250, a light emitting layer covering the pixel definition layer and the plurality of first electrodes is formed. The light emitting layer protrudes at the at least one separation protrusion, and the light emitting layer is electrically connected with the conductive shielding layer.

In step S260, a second electrode covering the light emitting layer is formed.

In addition, the manufacturing method according to an embodiment of the present disclosure may further include step S270.

In step S270, a color filter layer including a plurality of light filtering portions is formed on the side of the second electrode away from the substrate. The first electrodes and the light filtering portions are opposite to each other one to one in a direction perpendicular to the substrate, as shown in FIG. 9.

The structures in steps of the manufacturing method of the embodiments of the present disclosure have been described in detail in the embodiments of the display panel above, and will not be described in detail here.

It should be noted that although various steps of the manufacturing method of the present disclosure are described in a specific order in the drawings, this does not require or imply that the steps must be performed in this specific order, or that all of the steps shown must be performed to achieve the desired result. Additionally or alternatively, certain steps may be omitted, multiple steps may be combined into one step, and/or one step may be decomposed into multiple steps, and so on.

An embodiment of the present disclosure further provides a display device, including the display panel of any of the foregoing embodiments. For the structure of the display panel, reference may be made to the embodiments of the display surface above, which will not be repeated here. The display device of the present disclosure may be an electronic device with an image display function, such as a mobile phone or a tablet computer, which will not be listed one by one here.

Those skilled in the art will easily think of other embodiments of the present disclosure after considering the specification and practicing the invention disclosed herein. The present disclosure is intended to cover any variations, uses, or adaptive changes of the present disclosure. These variations, uses, or adaptive changes follow the general principles of the present disclosure and include common knowledge or conventional technical means in the technical field that are not disclosed in the present disclosure. The description and embodiments are only regarded as exemplary, and the true scope and spirit of the present disclosure are defined by the appended claims.

1. A display panel, comprising:
a driving backplane comprising a substrate, at least one wiring layer and a planarization layer, wherein the at least one wiring layer is arranged on a side of the substrate, and the planarization layer covers the at least one wiring layer;
a first electrode layer arranged on a surface of the planarization layer away from the substrate, and comprising a plurality of first electrodes spaced apart from each other;
a pixel definition layer arranged on the surface of the planarization layer away from the substrate and exposing each of the plurality of first electrodes, wherein the pixel definition layer is provided with at least one separation protrusion which protrudes along a direction away from the substrate, and an orthographic projection of the at least one separation protrusion on the planarization layer is located outside the first electrodes;
a conductive shielding layer arranged on a side of the planarization layer away from the substrate and insulated from the first electrodes, wherein an orthographic projection of the conductive shielding layer on the planarization layer is located outside the first electrodes;
a light emitting layer covering the pixel definition layer and the first electrodes, wherein the light emitting layer protrudes at the at least one separation protrusion, and the light emitting layer is electrically connected to the conductive shielding layer; and
a second electrode covering the light emitting layer.

2. The display panel according to claim 1, wherein the conductive shielding layer covers at least a partial region of the at least one separation protrusion, and the light emitting layer covers the conductive shielding layer and is in direct contact with the conductive shielding layer.

3. The display panel according to claim 1, wherein the conductive shielding layer is connected to the second electrode.

4. The display panel according to claim 2, wherein:
the at least one separation protrusion comprises at least one annular separation ring, and one of the at least one separation ring surrounds outside of one of the first electrodes;
the conductive shielding layer comprises at least one shielding ring, and at least partial region of one of the at least one protrusion is provided with one of the at least one shielding ring; and
any one of the at least one separation ring and a shielding ring which covers the one of the at least one separation ring surrounds a same one of the first electrodes.

5. The display panel according to claim 4, wherein the number of the at least one separation ring is the same as the number of the first electrodes, and each of the first electrodes is surrounded by one of the at least one separation ring, and at least partial region of each of the at least one separation ring is covered by one of the at least one shielding ring.

6. The display panel according to claim 5, wherein the at least one separation ring is connected to form an integral structure, and the at least one shielding ring is connected to form an integral structure.

7. The display panel according to claim 6, wherein the at least one shielding ring is connected to the second electrode.

8. The display panel according to claim 7, wherein at least a part of the at least one shielding ring is connected to the second electrode through at least one first via hole penetrating the light emitting layer, and an orthographic projection of the at least one first via hole on the planarization layer is located between two adjacent ones of the plurality of first electrodes.

9. The display panel according to claim 7, wherein:
the driving backplane comprises a pixel region and a peripheral region located outside the pixel region;
an orthographic projection of each of the plurality of first electrodes on the driving backplane is located in the pixel region;
an orthographic projection of an edge of the second electrode on the driving backplane is located in the peripheral region;
the conductive shielding layer further comprises at least one connection body connected to the at least one shielding ring, and an orthographic projection of each of the at least one connection body on the driving backplane extends from the pixel region to the peripheral region; and
the second electrode is connected to the at least one shielding ring through the at least one connection body.

10. The display panel according to claim 3, wherein at least a part of the at least one wiring layer comprises a connection portion connected to the second electrode, and the at least one shielding ring is connected to the connection portion through a second via hole penetrating the planarization layer.

11. The display panel according to claim 3, wherein the conductive shielding layer is arranged on the surface of the planarization layer away from the substrate, and is spaced apart from the first electrodes.

12. The display panel of claim 1, wherein the conductive shielding layer comprises a first conductive layer, a second conductive layer and a third conductive layer which are sequentially stacked in a direction away from the substrate.

13. The display panel according to claim 12, wherein materials of the first conductive layer and the third conductive layer are both metal titanium, and a material of the second conductive layer is metal aluminum.

14. The display panel according to claim 1, wherein the pixel definition layer has at least one extension portion, each of the at least one the extension portion is arranged on a surface of a corresponding one of the first electrodes away from the substrate, and has an opening exposing the corresponding one of the first electrodes;
wherein a surface of each of the at least one separation protrusion away from the driving backplane is located on a side of the at least one extension portion away from the driving backplane.

15. The display panel according to claim 14, wherein the pixel definition layer has a groove between one of the at least one separation protrusion and an adjacent extension portion.

16. The display panel according to claim 1, wherein the light emitting layer comprises multiple light emitting sub-layers connected in series, and at least one of the multiple light emitting sub-layers is connected in series with an adjacent one of the light emitting sub-layers through a charge generation layer.

17. The display panel according to claim 1, wherein:
the conductive shielding layer covers a partial region of a surface of each of the at least one the separation protrusion away from the substrate;
the second electrode protrudes in a region corresponding to the at least one separation protrusion to form a first protruding region; and
a region of the first protruding region corresponding to the conductive shielding layer protrudes in a direction away from the conductive shielding layer to form a second protruding region.

18. A method for manufacturing a display panel, comprising:
forming a driving backplane, wherein the driving backplane comprises a substrate, at least one wiring layer and a planarization layer, the at least one wiring layer is arranged on a side of the substrate, and the planarization layer covers the at least one wiring layer;
forming a first electrode layer on a surface of the planarization layer away from the substrate, wherein the first electrode layer comprises a plurality of first electrodes spaced apart from each other;
forming a pixel definition layer on the surface of the planarization layer away from the substrate, wherein the pixel definition layer exposes each of the plurality of first electrodes, the pixel definition layer is provided with at least one separation protrusion which protrudes along a direction away from the substrate, and an orthographic projection of the at least one separation protrusion on the planarization layer is located outside the first electrodes;
forming a conductive shielding layer covering at least a partial region of the at least one separation protrusion;
forming a light emitting layer covering the pixel definition layer, the plurality of first electrodes and the conductive shielding layer, wherein the light emitting layer protrudes at the at least one separation protrusion, and the light emitting layer is in direct contact with the conductive shielding layer; and
forming a second electrode covering the light emitting layer.

19. A method for manufacturing a display panel, comprising:
forming a driving backplane, wherein the driving backplane comprises a substrate, at least one wiring layer and a planarization layer, the at least one wiring layer is arranged on a side of the substrate, and the planarization layer covers the at least one wiring layer;
forming a first electrode layer on a surface of the planarization layer away from the substrate, wherein the first electrode layer comprises a plurality of first electrodes spaced apart from each other;
forming a conductive shielding layer on the surface of the planarization layer away from the substrate, wherein the conductive shielding layer is spaced apart from the first electrodes;
forming a pixel definition layer on the surface of the planarization layer away from the substrate, wherein the pixel definition layer exposes each of the plurality of first electrodes, the pixel definition layer is provided with at least one separation protrusion which protrudes along a direction away from the substrate, and an orthographic projection of the at least one separation protrusion on the planarization layer is located outside the first electrodes;
forming a light emitting layer covering the pixel definition layer and the plurality of first electrodes, wherein the light emitting layer protrudes at the at least one separation protrusion, and the light emitting layer is electrically connected with the conductive shielding layer; and
forming a second electrode covering the light emitting layer.

20. A display device, comprising the display panel of claim 1.
